(19) United States
(12) Patent Application Publication
(10) Pub. No.: US 2016/0268982 A1
(43) Pub. Date: Sep. 15, 2016

(54) LIGHT RECEIVING CIRCUIT AND OPTICAL COUPLING DEVICE

(71) Applicant: KABUSHIKI KAISHA TOSHIBA, Tokyo (JP)

(72) Inventors: Masayuki SUGIZAKI, Yokohama Kanagawa (JP); Shigeyuki SAKURA, Kawasaki Kanagawa (JP)

(21) Appl. No.: 14/828,169

(22) Filed: Aug. 17, 2015

(30) Foreign Application Priority Data
Mar. 12, 2015 (JP) 2015-050045

(51) Int. Cl. H03F 3/08; H01L 31/14; H01L 27/144; H03F 1/02

(52) U.S. Cl. CPC H03F 3/082; H03F 1/0205; H01L 31/145; H01L 27/1443; H03F 2200/129

(57) ABSTRACT

According to an embodiment, a light receiving circuit includes a light receiving element, a first MOS transistor of a first conductivity type that has a first gate electrode connected to the light receiving element, a first source electrode connected to a reference potential line, and a first drain electrode connected to a first load circuit at a first node, and operates in a saturation region, a second MOS transistor of a second conductivity type that has a second gate electrode connected to the first node, a second source electrode connected to an output terminal, and a second drain electrode connected to the reference voltage terminal, a second load circuit connected between a power supply terminal and the second source electrode, and a feedback resistor element connected between the first gate electrode and the output terminal.

### CROSS-REFERENCE TO RELATED APPLICATION

This application is based upon and claims the benefit of priority from Japanese Patent Application No. 2015-050045, filed Mar. 12, 2015, the entire contents of which are incorporated herein by reference.

### FIELD

Embodiments described herein relate generally to a light receiving circuit and an optical coupling device.

### BACKGROUND

An optical coupling element, an optical communication device, and the like are widely used for various electronic devices for industrial, communication, and home applications. These days, the light emission efficiency for a light emission element used for the devices, is improving.

Intensity of a light signal which is handled in the light receiving circuit may range from a weak level to an extremely strong level, and thus a light receiving circuit with a wide dynamic range is needed.

### DESCRIPTION OF THE DRAWINGS

FIG. 1 is a circuit diagram illustrating a light receiving circuit according to a first embodiment.

FIG. 2 is a circuit diagram illustrating a light receiving circuit corresponding to the light receiving circuit according to the first embodiment.

FIG. 3 is a circuit diagram of a light receiving circuit of a comparison example.

FIG. 4A is a graph depicting frequency characteristics of a light receiving circuit according to the first embodiment.

FIG. 4B is a graph depicting frequency characteristics of a light receiving circuit of a comparison example.

FIG. 5 is a graph depicting pulse response characteristics of a light receiving circuit according to the first embodiment in comparison with pulse response characteristics of a light receiving circuit of a comparison example.

FIG. 6 is a circuit diagram illustrating a light receiving circuit according to a second embodiment.

FIG. 7 is a circuit diagram illustrating a light receiving circuit according to a third embodiment.

FIG. 8 is a graph comparing pulse response characteristics of light receiving circuits according to different embodiments.

FIG. 9 is a circuit diagram illustrating a light receiving circuit according to a fourth embodiment.

FIG. 10A is a block diagram illustrating an optical coupling device according to a fifth embodiment.

FIG. 10B is a sectional diagram illustrating a structure of the optical coupling device according to the fifth embodiment.

FIG. 11 is a block diagram illustrating an optical communication system according to a sixth embodiment.

### DETAILED DESCRIPTION

Example embodiments provide a light receiving circuit and an optical coupling device which maintain frequency characteristics and operate at a low voltage.

In general, according to one embodiment, a light receiving circuit includes: a light receiving element; a first MOS transistor of a first conductivity type that has a first gate electrode which is connected to the light receiving element, a first source electrode which is connected to a reference voltage terminal, and a first drain electrode which is coupled to a first load circuit at a first node, and operates in a saturation region; a second MOS transistor of a second conductivity type that has a second gate electrode which is connected to the first node, a second source electrode which is connected to an output terminal, and a second drain electrode which is connected to the reference voltage terminal; a second load circuit that is connected between a power supply terminal and the second source electrode; and a feedback resistor element that is connected between the first gate electrode and the output terminal.

Hereinafter, example embodiments are described with reference to the drawings.

### First Embodiment

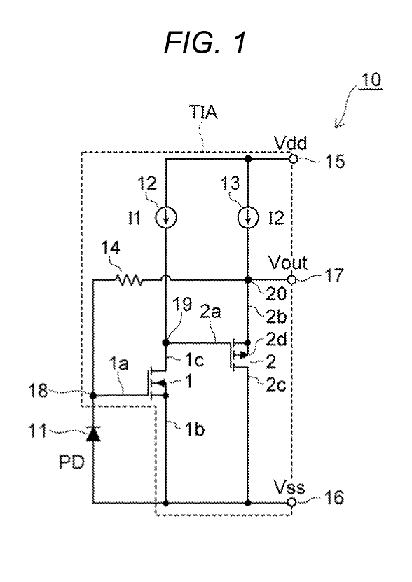

FIG. 1 is a circuit diagram illustrating a light receiving circuit according to a first embodiment.

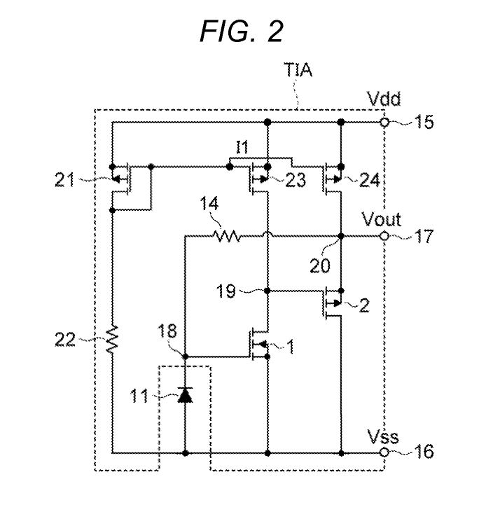

FIG. 2 is a circuit diagram of a light receiving circuit in which the circuit of FIG. 1 is illustrated as a more specific circuit element.

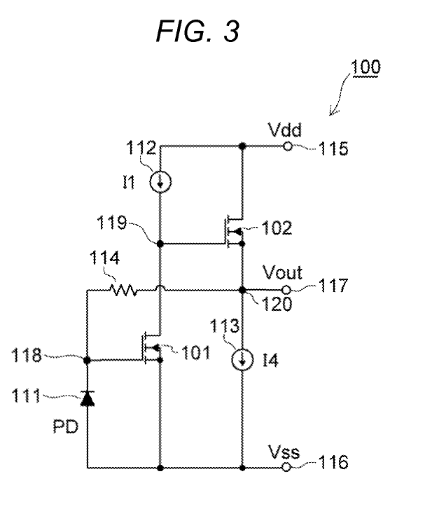

FIG. 3 is a circuit diagram of a light receiving circuit of a comparison example.

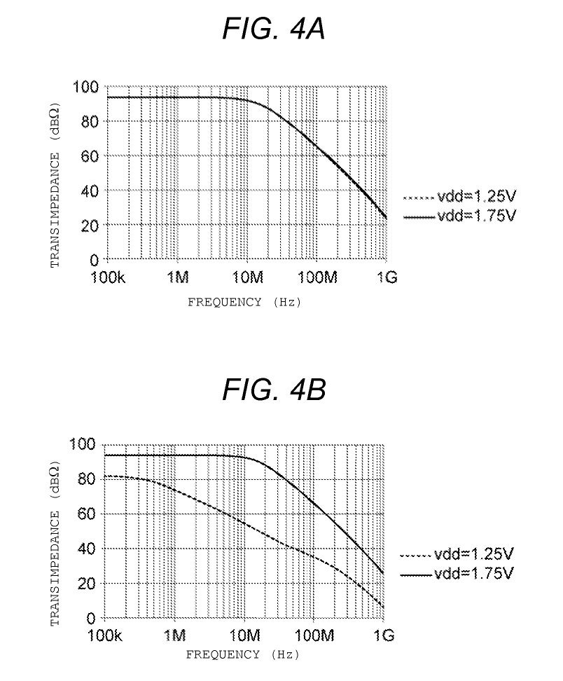

FIG. 4A is a graph depicting frequency characteristics of a light receiving circuit according to the present embodiment. FIG. 4B is a graph depicting frequency characteristics of a light receiving circuit of a comparison example.

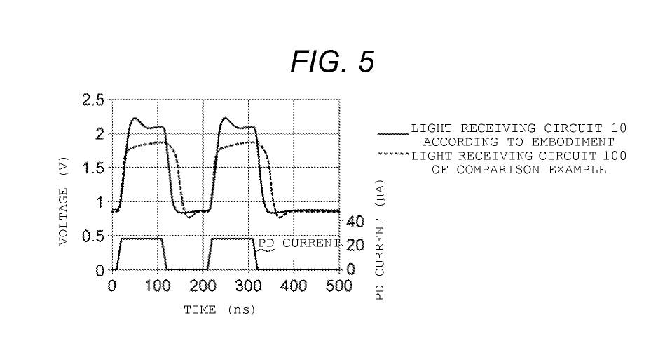

FIG. 5 is a graph that depicts pulse response characteristics of a light receiving circuit according to the present embodiment in comparison with pulse response characteristics of a light receiving circuit of a comparison example.

As illustrated in FIG. 1, a light receiving circuit 10 according to the first embodiment includes a light receiving element 11, an amplification transistor 1, an output transistor 2, a first load circuit 12, a second load circuit 13, and a feedback resistor element 14.

The light receiving circuit 10 is connected between a power supply terminal 15 and a reference voltage terminal 16. Here, a potential Vss of the reference voltage terminal 16 is the lowest potential among potentials which are connected to the light receiving circuit 10, and is typically a ground potential (e.g., 0 V). A potential Vdd of the power supply terminal 15 is the highest potential among potentials which are connected to the light receiving circuit 10, and is, for example, 2.5 V with respect to the ground potential. For the potential Vss and the potential Vdd, it is preferable if the above-described potential relationship is maintained. Yet, one or both of the potential Vss of the reference voltage terminal 16 and the potential Vdd of the power supply terminal 15 may be a negative potential.

In the present specification, it is assumed that a saturation region of a MOS transistor indicates a region in which a drain current (output current) is proportional to square of a voltage difference between a gate-source voltage and a threshold voltage, in output characteristics between a drain and a source of a MOS transistor. More specifically, a drain current Id in a saturation region is represented as follows.

Id=(k/2)×(Vg−Vt)² Expression (1)

Here, Vg is a gate-source voltage of a MOS transistor, and Vt is a gate threshold voltage of a MOS transistor. In addition, k is represented by k=(W/L)·μ·Cox. W and L are respectively a gate width and a gate length of a MOS transistor. μ is mobility of a carrier (electron if n-channel, hole if p-channel) in a channel, and Cox is a capacitance which is generated by the presence of a gate oxide film.

A drain current represents substantially a constant value, with respect to a drain-source voltage, in the saturation region of a MOS transistor. In contrast to this, the linear region of a MOS transistor is a region in which a drain current has a linear term of a drain-source voltage which includes a voltage difference between a gate-source voltage and a threshold voltage in a proportionality constant, in output characteristics of a MOS transistor. More specifically, the drain current Id in a linear region is represented as follows.

Id=k·{(Vg−Vt)·Vd−(½)·Vd²} Expression (2)

Here, Vd is a drain-source voltage of a MOS transistor, and the other parameters are the same as the parameters in expression (1).

A drain-source voltage in a boundary region between the saturation region and the linear region of a MOS transistor is equal to a voltage difference between a gate-source voltage and a threshold voltage, and a drain-source voltage at this time may be referred to as an overdrive voltage. It is assumed that saturation of an output waveform or the like indicates a case in which a voltage waveform is different from an expected output voltage waveform, for example, a distorted waveform is represented, as a MOS transistor related to an output voltage waveform operates at a linear region, in an output voltage waveform of a light receiving circuit.

In addition, although a threshold voltage of a p-channel MOS transistor is typically represented by a negative value, in the present disclosure, representation of the threshold value may be treated as a positive value (that is, absolute value notation may be omitted from such a value), while not being particularly limited to any such requirement.

The light receiving element 11 is connected between the reference voltage terminal 16 and an input node 18. The light receiving element 11 is, for example, a silicon photodiode. The light receiving element 11 may also be or include a photoelectric conversion element such as a silicon PIN photodiode or an avalanche photodiode, according to an intended light transmission distance, communication speed, or the like. In addition, the light receiving element 11 may be a photodiode which uses a semiconductor material other than silicon.

The amplification transistor (first MOS transistor) 1 includes a gate electrode 1a which is connected to the light receiving element 11 at the input node 18, a source electrode 1b which is connected to the reference potential Vss, and a drain electrode 1c which inverts a voltage that is input to the gate electrode 1a and outputs the inverted voltage. The drain electrode 1c of the amplification transistor 1 is directly connected to a first load circuit 12 at an internal output node 19 (first node). The amplification transistor 1 is, for example, an n-channel MOSFET.

The amplification transistor 1 is connected in series to the first load circuit 12. The first load circuit 12 includes a current source having a current value I1. The first load circuit 12 is connected between the power supply potential Vdd and the internal output node 19.

The amplification transistor 1 is configured as a source ground amplification circuit in which the operating point is set by the first load circuit 12. Setting of an operating point of a MOS transistor means setting of a drain current in the saturation region of the MOS transistor. In other words, it means that a current value of the load circuit is set in such a manner that a desired drain current of the MOS transistor flows, according to expression (1) described above.

The output transistor (second MOS transistor) 2 includes a gate electrode 2a which is connected to the drain electrode 1c of the amplification transistor 1 at the internal output node 19, a source electrode 2b which is connected both to the second load circuit 13 and an output terminal 17 at an output node 20, and a drain electrode 2c which is connected to the reference potential Vss. The output transistor 2 is a MOS transistor of a conductivity type which is different from the amplification transistor 1, and is, for example, a p-channel MOSFET if the amplification transistor 1 is an n-channel MOSFET. In operation, the light receiving circuit 10 has an absolute value Vgs2 of a gate-source voltage of the output transistor 2 that is smaller than a threshold voltage Vth1 of the amplification transistor 1. The output transistor 2 is an n-channel MOSFET if the amplification transistor 1 is a p-channel MOSFET. A potential of the source electrode 2b of the output transistor 2 is changed by an output signal, and thereby a back gate electrode 2d is connected to a source electrode 2b.

The second load circuit 13 includes a current source having a current value I2. The second load circuit 13 is connected between the power supply potential Vdd and an output node 20 to which the output terminal 17 and the source electrode 2b of the output transistor 2 are connected.

The output transistor 2 is connected in series to the second load circuit 13. The output transistor 2 is a source follower circuit whose operating point is set by the second load circuit 13. The source follower circuit, which includes the output transistor 2 and the second load circuit 13, is an output circuit which receives an output of a source ground amplification circuit that includes the amplification transistor 1 and the first load circuit 12 with a high impedance, and outputs the received signal with a low impedance.

As illustrated in FIG. 2, a current mirror circuit may be used for current sources of the first and second load circuits 12 and 13. A transistor 21, which is in a diode-connection, is connected between the power supply potential Vdd and the ground potential Vss. For the transistor 21, a current value which is used as a reference is set by a resistor element 22, which is connected between the transistor 21 and the ground potential Vss.

A current mirror 23 is connected between the power supply potential Vdd and the output node 19. A current mirror 24 is connected between the power supply potential Vdd and the output node 20. Each gate electrode of the current mirrors 23 and 24 is connected to a gate electrode of the transistor 21. Current values of the current mirrors 23 and 24 are determined by the transistor 21 and a transistor size of the respective current mirrors 23 and 24. That is, if a size ratio between the transistor 21 and the respective transistors of the current mirrors 23 and 24 is, for example, 1:1:1, values of currents flowing through the respective transistors are equal to each other.

An element which includes a resistor element may be used for the first and second load circuits 12 and 13, in addition to a current source circuit which includes a current mirror circuit or the like.

The feedback resistor element 14 is connected between the input node 18 and the output node 20. Thus, the light receiving circuit 10 includes a transimpedance amplification circuit TIA in which the feedback resistor element 14 is connected between an input and an output of an inversion amplification circuit that includes a source ground amplification circuit and a source follower circuit which are in a cascade connection to each other.

The transimpedance amplification circuit TIA receives a current which is proportional to the amount of light received by the light receiving element 11, and converts the current into a voltage, and outputs the voltage.

Next, an operation of the light receiving circuit according to the first embodiment is described using FIG. 2.

It is assumed that the reference potential Vss is a ground potential and is 0 V. Thus, the power supply voltage is equal to the power supply potential Vdd.

To begin with, the case in which no signal is present is described. No signal in the light receiving circuit 10 means that there is no light irradiation into the light receiving element 11 and the light receiving element 11 consequently does not generate an output current. Any current which is generated as a dark current or the like of the light receiving element 11 can be disregarded in this context.

At the time of no signal, the light receiving element 11 does not output a current, and thus a voltage drop does not occur across the feedback resistor element 14. For this reason, a voltage Vout of the output node 20 is equal to a voltage of the input node 18, that is, a gate-source voltage Vgs1 of the amplification transistor 1 (i.e., Vout=Vgs1).

The drain electrode 1c of the amplification transistor 1 is connected to the gate electrode 2a of the output transistor 2, and thus a drain-source voltage Vds1 of the amplification transistor 1 determines the gate-source voltage Vgs2 of the output transistor 2. More specifically, the drain-source voltage Vds1 of the amplification transistor 1 is equal to a difference between the voltage Vout of the output node 20 and the gate-source voltage Vgs2 of the output transistor (Vds1=Vout−Vgs2=Vgs1−Vgs2). The gate-source voltage Vgs2 of the output transistor 2 is determined by expression (1) in such a manner that the current value I2 of the current mirror 24 is set as the drain current Id2.

Even if the drain-source voltage Vds1 is decreased to the overdrive voltage Vov1, the amplification transistor 1 may still operate in a saturation region. That is, the drain-source voltage Vds1 needs to be equal to or higher than the overdrive voltage Vov1. That is, when Vds1 Vov1 is satisfied, the amplification transistor 1 operates in the saturation region. In addition, as described above, Vds1=Vgs1−Vgs2 is satisfied, and thereby the following expression is obtained.

Vgs1−Vgs2≧Vov1

Here, if Vgs1 is replaced by the quantity Vov1+Vth1 (note: Vov1=Vgs1−Vth1), the following expression is obtained.

Vov1+Vth1−Vgs2≧Vov1

∴Vth1≧Vgs2 Expression (3)

Here, Vth1 is a threshold voltage of the amplification transistor 1; Vov1 is an overdrive voltage of the amplification transistor 1; and the overdrive voltage Vov1 is equal to a difference between the gate-source voltage Vgs1 and the threshold voltage Vth1 (i.e., Vov1=Vgs1−Vth1).

The amplification transistor 1 operates at a saturation region by expression (1) and expression (3). The gate-source voltage Vgs1 at this time is equal to the threshold voltage Vth1 or a voltage higher than the threshold voltage Vth1, and is a voltage value by which the drain current Id1 that is substantially equal to the current value I1 of the current mirror 23 flows (see expression (1)).

Next, when the light receiving element 11 receives light and outputs a current, operation of the light receiving circuit 10 is described. The light receiving element 11 receives light and generates an output current according to the received amount of light. The current which is output from the light receiving element 11 flows toward the input node 18 from the output node 20 via the feedback resistor element 14. The voltage Vout of the output node 20 is increased by a voltage drop which is generated by the feedback resistor element 14 according to the current flowing through the feedback resistor element 14. That is, the output voltage Vout of the light receiving circuit 10 becomes a voltage which is substantially proportional to an output current that is generated by the light receiving element 11. Thus, the light receiving circuit 10 outputs a maximum voltage when light is irradiated into the light receiving element 11 and light receiving element 11 outputs a current. The maximum output voltage is calculated as follows.

As the output voltage of the light receiving circuit 10 increases, a voltage between the power supply terminal 15 and the output terminal 17 is decreased. A voltage between the power supply terminal 15 and the output terminal 17 is applied to both ends of the current mirror 24, and thereby a maximum value of the output voltage is determined by a condition in which the current mirror 24 deviates from the saturation region. That is, when a voltage across the current mirror 24 is equal to an overdrive voltage Vov24, the output voltage becomes a maximum value. The overdrive voltage Vov24 of the current mirror 24 is the difference between a gate-source voltage Vgs24 of the current mirror 24 and a threshold voltage Vth24, and thus Vov24=Vgs24−Vth24. A voltage as high as a gate-source voltage of the output transistor 2 is applied between a drain and a source of the current mirror 23 and between a drain and a source of the current mirror 24. For this reason, the current mirror 24 deviates from the saturation region before the current mirror 23. Thus, the maximum output voltage Vout (max) is represented by the following expression.

Vout(max)=Vdd−Vov24 Expression (4)

The gate-source voltage Vgs2 of the output transistor 2 is substantially a constant value which is determined by a current that is set by the current mirror 24.

The gate electrode 2a of the output transistor 2 is connected to the drain electrode 1c of the amplification transistor 1. For this reason, the drain-source voltage Vds1 of the amplification transistor 1 is equal to a value which is obtained by subtracting the gate-source voltage Vgs2 of the output transistor 2 from the voltage Vout of the output node 20 (i.e., Vds1=Vout−Vgs2). The gate-source voltage Vgs2 is set by a current which is set by the current mirror 24, and is approximately a constant value. As described above, the voltage Vout of the output node 20 is a voltage higher than a voltage at the time of no signal, and the gate-source voltage Vgs2 is nearly constant, and thus the drain-source voltage Vds1 of the amplification transistor 1 is higher than the overdrive voltage Vov1. Thus, when there is a signal, the amplification transistor 1 is guaranteed to operate in the saturation region. If a resistor element or the like is used instead of a current mirror as a load circuit, there are no overdrive voltage restrictions, and thereby it is possible to reduce a voltage which may be applied to both ends of a load circuit. Thus, it is possible to increase a maximum output voltage of the light receiving circuit 10.

Next, an operation and an effect of light receiving circuit 10 according to the present embodiment is compared with a light receiving circuit of a comparison example.

As illustrated in FIG. 3, a light receiving circuit 100 of a comparison example is different from the light receiving circuit 10 according to the above-described embodiment in that an output transistor 102 is an n-channel MOSFET of a conductivity type which is the same as an amplification transistor 101, and the light receiving circuit 100 is a source follower which uses a load circuit 113 as a load. That is, the output transistor 102 is connected between the power supply potential Vdd and an output node 120, and the load circuit 113 is connected between the output node 120 and the reference potential Vss.

In the light receiving circuit 100 of the comparison example, as a minimum output voltage Vout0′ at the time of no signal, a gate-source voltage Vgs101 of the amplification transistor 101 is output, in the same manner as light receiving circuit 10 according to the first embodiment. In light receiving circuit 100 of the comparison example, at the time of no signal, a MOS transistor which moves from a saturation region to a linear region is not present, and thereby Vout0′=Vgs101 is satisfied without a special condition.

When there is a signal, a maximum output voltage Vout(max)′ is obtained as follows.

In the light receiving circuit 100 of the comparison example, if the maximum output voltage Vout(max)′ is output, with the output transistor 102 is configured as a source follower, the output voltage Vout increases, and a potential of a gate electrode of the output transistor 102 increases. Thus, a current mirror 112 which is connected between the power supply potential Vdd and a gate electrode of the output transistor 102 may deviate from a saturation region.

When the current mirror 112 moves from a saturation region to a linear region, if a voltage between both ends of the current mirror 112 is referred to as Vov112 and a gate-source voltage of the output transistor 102 is referred to as Vgs102, the maximum output voltage Vout (max)′ is obtained by the following expression.

Vout(max)′=Vdd−Vov112−Vgs102 Expression (5)

For example, in expression (5), if the power supply potential Vdd is set as 2.5 V, the overdrive voltage Vov112 of the current mirror 112 is set as 0.4 V, a transistor with a low threshold is used as the output transistor 102, and Vgs102 is set as 0.5 V, the following expression is obtained.

Vout(max)′=2.5 V−0.4 V−0.5 V=1.6 V

Meanwhile, in a case of light receiving circuit 10 according to the first embodiment, at the time of no signal, an output current is zero without light irradiation into light receiving element 11. Thus, the voltage Vout of the output node 20 is equal to a voltage of the input node 18, that is, the gate-source voltage Vgs1 of the amplification transistor 1. An output voltage at this time is a minimum output voltage Vout0 of light receiving circuit 10 according to the first embodiment. The gate-source voltage Vgs1 is determined by a drain current which is set by the first load circuit 12 that determines the operating point, and may be set as 1 V in the same manner as a case of light receiving circuit 100 of the comparison example, for example.

At this time, the relationship of expression (3) must be satisfied between the threshold voltage Vth1 of the amplification transistor 1 and the gate-source voltage Vgs2 of the output transistor 2. Expression (3) is again.

Vth1≧Vgs2 Expression (3)

Thus, the magnitude of a minimum output voltage satisfies a condition of expression (3), and thereby the light receiving circuit 10 according to the first embodiment may achieve the same value as the minimum output voltage of the light receiving circuit 100 of the comparison example.

As described above, when there is a signal, the maximum output voltage Vout(max) of the light receiving circuit 10 according to the first embodiment is equal to a voltage which is obtained by subtracting a minimum voltage of both ends of the current mirror 24 from the power supply voltage Vdd. Expression (4) representing the maximum output voltage Vout(max) of the light receiving circuit 10 is again.

Vout(max)=Vdd−Vov24 Expression (4)

If the power supply voltage Vdd=2.5 V and Vov24=0.4 V, the following value is obtained by using expression (4).

Vout(max)=2.5 V−0.4 V=2.1 V

As described above, a maximum output voltage Vout(max)′ of light receiving circuit 100 of the comparison example is 1.6 V, and in the light receiving circuit 10 according to the first embodiment a higher output voltage is obtained.

As described above, a dynamic range of light receiving circuit 10 according to the first embodiment is 2.1 V−1 V=1.1 V, and in contrast to this, a dynamic range of light receiving circuit 100 of the comparison example is 1.6 V−1 V=0.6V. In the light receiving circuit 100 of the comparison example, the gate-source voltage Vgs102 of the output transistor 102 is connected in series in addition to a load circuit of one stage. In contrast to this, in the light receiving circuit 10, a load circuit of the current mirror 24 or the like of only one stage is connected between the power supply terminal 15 and the output terminal 17 (output node 20). For this reason, it is possible to reduce a voltage between the power supply terminal 15 and the output terminal 17, and thereby the light receiving circuit 10 may output a higher output voltage.

In addition, in the light receiving circuit 10, a voltage between the power supply terminal 15 and the output terminal 17 may be reduced to a lower voltage, and thereby it is possible to increase a voltage which is applied between drains and sources of the amplification transistor 1 and the output transistor 2. For this reason, it is possible to improve frequency characteristics of the amplification transistor 1 and the output transistor 2, and to improve power supply voltage dependence of small signal frequency characteristics and pulse response characteristics of the light receiving circuit 10, as described below.

As illustrated in FIG. 4A, in the light receiving circuit 10, frequency characteristics are almost unchanged even if the power supply voltage Vdd is 1.75 V or 1.25 V. Meanwhile, as illustrated in FIG. 4B, in the light receiving circuit 100 of the comparison example, if the power supply voltage Vdd is 1.75 V, the frequency characteristics thereof nearly matches the frequency characteristics of light receiving circuit 10, but if the power supply voltage Vdd is set to 1.25 V, the frequency characteristics of light receiving circuit 100 are remarkably degraded in comparison to light receiving circuit 10 (and also in comparison to the light receiving circuit 100 having Vdd set to 1.75 V).

As illustrated in FIG. 5, in the light receiving circuit 10, frequency characteristics of a large amplitude, that is, pulse response characteristics also hardly generate saturation of an output waveform, compared to the light receiving circuit 100 of the comparison example, and approximately the same output voltage (solid line) as that of the light receiving circuit 100 (dotted line) is obtained in the input current waveform. Meanwhile, in the light receiving circuit 100 of the comparison example, since a dynamic range is narrow, a pulse width in which an output waveform (dotted line) is distorted is formed so as to be wider than a pulse width of an output current of the light receiving element 11 (labeled PD current). In the pulse response characteristics of FIG. 5, the power supply voltage Vdd is set as 2.5V, and resistance values of the feedback resistor elements 14 and 114 are set as 50 kχ. In addition, a maximum output current of the light receiving element is set as 25 μA.

As described above, in the light receiving circuit 10, the output transistor 2 uses a source follower circuit using a MOS transistor with a polarity different from that of the amplification transistor, a p-channel MOS transistor in the example described above. For this reason, the light receiving circuit 10 also allows an increase of an output voltage which is determined by a load circuit of a source follower. Meanwhile, in the light receiving circuit 10, the gate electrode 2a of the output transistor 2 is connected to the drain electrode 1c of the amplification transistor 1, and design parameters of the amplification transistor 1 and the output transistor 2 are set so as to satisfy the conditions of expression (3). For this reason, the drain-source voltage Vds1 of the amplification transistor 1 operates at a voltage equal to or higher than the overdrive voltage Vov1, and an operation in the saturation region of the amplification transistor 1 is guaranteed. Thus, in the light receiving circuit 10, a dynamic range is expanded.

Presently, low power consumption in optical devices is strongly demanded, and for this reason, a low voltage operation is demanded for a component or an element which configures a device. In the light receiving circuit 10, a low voltage may be applied to an output load circuit 13, and thereby there is room for a voltage range in which the amplification transistor 1 and the output transistor 2 may operate. For this reason, even if a power supply voltage is decreased, it is possible to reduce degradation of frequency characteristics and pulse response characteristics. Thus, in the light receiving circuit 10, a lower voltage operation may be performed, and it is possible to thus contribute to a low power consumption of a device.

For example, if a waveform of the output voltage Vout which is generated in the output terminal 17 of the light receiving circuit 10 is saturated and is not distorted, or the distortion is sufficiently small, there may be a case in which the amplification transistor 1 operates by containing a portion of an amplitude of an output voltage in the linear region (expression (2)). For a distortion magnitude of the waveform of the output voltage Vout, an appropriate value is set by a connecting condition or the like of a circuit in a subsequent stage. This is also applied in the same manner as in a light receiving circuit according to another embodiment which is described hereinafter.

### Second Embodiment

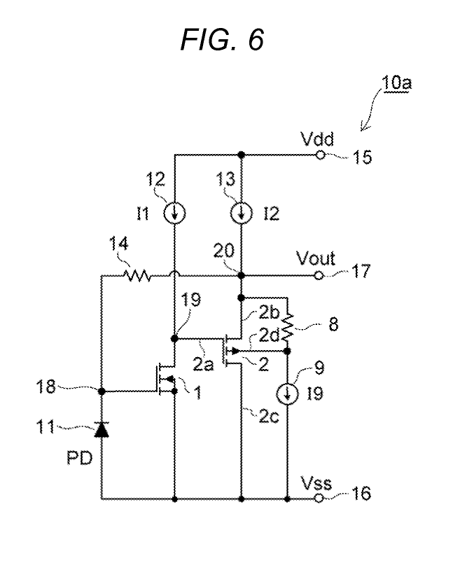

FIG. 6 is a circuit diagram illustrating a light receiving circuit according to a second embodiment.

In the light receiving circuit 10 according to the first embodiment described above, the threshold voltage of the output transistor 2 is set as a value lower than the threshold voltage Vth1 of the amplification transistor 1, and the gate-source voltage Vgs2 at the time of operating the output transistor 2 is set as a voltage equal to or lower than Vth1 (expression (1)). In order to set a low threshold voltage Vth2 of the output transistor 2, it is better if fabrication parameters are set so as to fabricate a p-channel MOSFET with a low threshold voltage, in a semiconductor fabrication process. However, a p-channel MOSFET with a stable low threshold voltage is difficult to fabricate. In addition, in order to fabricate a transistor with various threshold voltages, the number of fabrication processes is increased and cost is also increased. Therefore, by applying a voltage to a back gate electrode of a p-channel MOSFET from the outside, the threshold voltage is shifted, and a p-channel MOSFET with a low threshold voltage is achieved.

As illustrated in FIG. 6, a light receiving circuit 10a according to the second embodiment further includes a resistor element 8 for setting a threshold voltage, and a power supply (second power supply) 9 for setting a threshold voltage. The resistor element 8 is connected between the source electrode 2b of the output transistor 2 and the back gate electrode 2d. The power supply 9 is connected between the back gate electrode 2d and the reference potential Vss. The power supply 9 provides a constant current with a current value I9 flow through the resistor element 8, and thereby a voltage is generated on across the resistor element 8. A voltage is applied across the resistor element 8, in such a manner that a forward bias is applied between the source electrode 2b of the output transistor 2 and the back gate electrode 2d. The voltage which is applied between the source electrode 2b of the output transistor 2 and the back gate electrode 2d is (resistance value R8 of the resistor element 8)×(current value I9 of the power supply 9). As the potential of the back gate electrode 2d is lower than the potential of the source electrode 2b by R8×I9, the threshold voltage Vth2′ of the output transistor 2 is set as a low voltage value.

With the resistor element 8 and the power supply 9 for setting a threshold voltage provided, the output transistor 2 may stably generate a threshold voltage lower than the threshold voltage Vth1 of the amplification transistor 1, without substantially adding to the fabrication process. Thus, it is possible to achieve the light receiving circuit 10a with a wide dynamic range.

### Third Embodiment

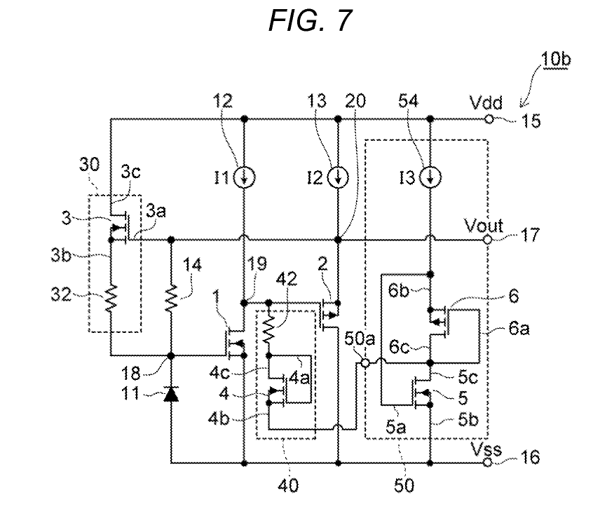

FIG. 7 depicts a circuit diagram illustrating a light receiving circuit according to a third embodiment.

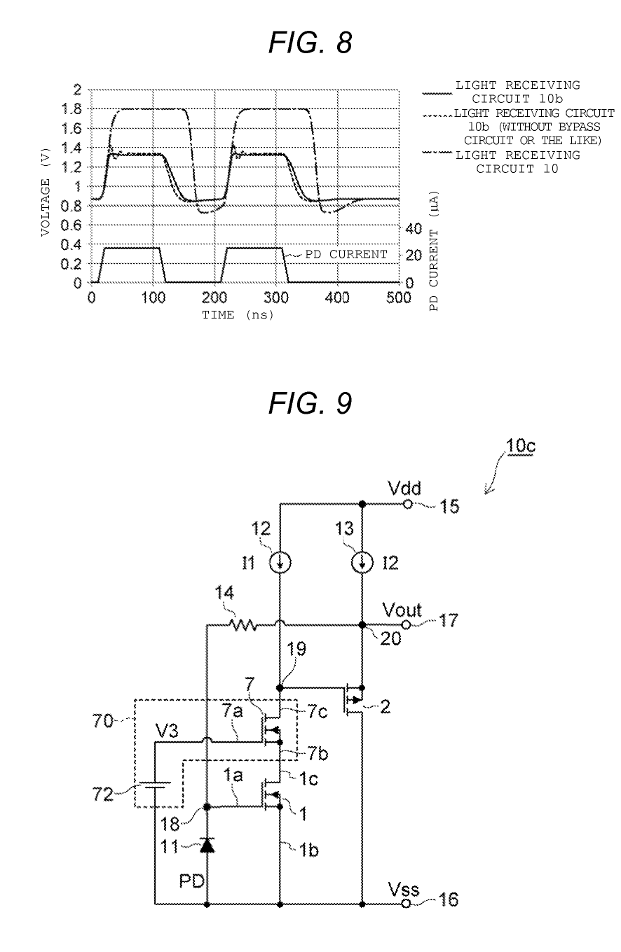

FIG. 8 is a graph depicting pulse response characteristics of the light receiving circuit (10b) according to the third embodiment and pulse response characteristics of the light receiving circuit (10) according to a the first embodiment for comparison.

In a light receiving circuit, in order to expand a dynamic range of an output, it is necessary to be able to handle an output current from the light receiving element over a wide range (e.g., from a low level value to a high level value). If light at a weak level is received by the light receiving, then a low current (small current value) is output from the light receiving element. If light at a high level is received, then a high current (large current value) is output from the light receiving element. Above some current level from the light receiving element, a load circuit of an output circuit deviates from a saturation region and moves to a linear region. For this reason, an output signal waveform is distorted and thereby a voltage signal with a pulse width different from a pulse width of an input signal waveform is generated, and thus it is necessary to prevent a MOS transistor from deviating from a saturation region. Therefore, in a light receiving circuit which has a wide dynamic range, an amplitude of an output signal which is output by an output circuit is limited, and a limiter circuit is added in such a manner that an output circuit does not operate in a linear region. However, if the level of an output signal waveform is limited by adding a limiter circuit, the amount of feedback for an amplifier is changed, and a light receiving circuit may become unstable. Therefore, it is necessary to further add a circuit which secures stable operation of a light receiving circuit at the time of limiter circuit operation, in addition to the limiter circuit.

As illustrated in FIG. 7, the light receiving circuit 10b according to the third embodiment includes a limiter circuit 30, a bypass circuit 40, and a voltage generation circuit 50. The other circuit elements are the same as those of the light receiving circuit 10, the same symbols or reference numerals are attached to the same elements, and detailed description thereof is omitted.

The limiter circuit 30 includes a limiter transistor 3 (third MOS transistor) and a resistor element 32. The limiter transistor 3 includes a gate electrode 3a which is connected to the output node 20, a source electrode 3b which is connected to one terminal of the resistor element 32, and a drain electrode 3c which is connected to the power supply potential Vdd. The other terminal of the resistor element 32 is connected to the input node 18. The resistor element 32 is connected to the output node 20 via a gate-source voltage of the limiter transistor 3, and thereby the resistor element 32 is effectively connected in parallel with the feedback resistor element 14, and a resistance value is set according to an intended dynamic range.

If the light receiving element 11 receives light and output a current, the current which is generated flows into the feedback resistor element 14. If an amount of light received by the light receiving element 11 is small, a current flowing through the feedback resistor element 14 is small, and a voltage across the feedback resistor element 14 is smaller than a threshold voltage of the limiter transistor 3. For this reason, a potential of the output node 20 increases according to the value of a current flowing through the feedback resistor element 14. The threshold voltage of the limiter transistor 3 is set so as not to turn on the limiter transistor 3, in a range in which the second load circuit 13 does not move from a saturation state to a linear region. If a current which is output from the light receiving element 11 is increased, and a voltage across the feedback resistor element 14 exceeds a threshold voltage of the limiter transistor 3, the limiter transistor 3 is turned on. If the limiter transistor 3 is turned on, an increase of a voltage across the feedback resistor element 14 is limited. For this reason, a voltage increase of the output node 20 is limited, and the second load circuit 13 is prevented from moving into a linear region from a saturation region. By doing this, if a large signal is input, the limiter circuit 30 operates in such a manner that the second load circuit 13 is prevented from deviating from a saturation region and a level of an output signal is not saturated.

The bypass circuit 40 includes a resistor element 42, and a bypass transistor 4 (fourth MOS transistor) which is in a diode-connection. The resistor element 42 is connected in series to the bypass transistor 4. The bypass circuit 40 is connected between an internal output node 19 and an output terminal 50a of a voltage generation circuit 50. The bypass transistor 4 is connected in a direction in which a current flows to an output terminal 50a from the internal output node 19. The resistor element 42 sets the value of a current flowing when the bypass transistor 4 is turned on.

The voltage generation circuit 50 includes an n-channel MOS transistor 5 (fifth MOS transistor), a p-channel MOS transistor 6 (sixth MOS transistor), and a load circuit 54. The load circuit 54, the p-channel MOS transistor 6, and the n-channel MOS transistor 5 are connected in series in this order, and are connected between the power supply potential Vdd and the reference potential Vss. The load circuit 54 is connected between the power supply potential Vdd and a source electrode 6b of the p-channel MOS transistor 6. A gate electrode 6a of the p-channel MOS transistor 6 is connected to a drain electrode 6c, and is connected to a drain electrode 5c of the n-channel MOS transistor 5. A gate electrode 5a of the n-channel MOS transistor 5 is connected to the source electrode 6b of the p-channel MOS transistor 6. A source electrode 5b of the n-channel MOS transistor 5 is connected to the reference potential Vss. The voltage generation circuit 50 outputs a potential equal to a potential of the internal output node 19 at the time of no signal from the output terminal 50a. The output terminal 50a is connected to the drain electrode 5c of the n-channel MOSFET 5.

The n-channel MOS transistor 5 is a MOSFET with the same polarity as that of the amplification transistor 1, and here is an n-channel MOSFET, if the amplification transistor 1 is an n-channel MOSFET. If the amplification transistor 1 is a p-channel MOSFET, the MOS transistor 5 is a p-channel MOSFET. The n-channel MOS transistor 5 and the amplification transistor 1 are set in such a manner that threshold voltages thereof are substantially equal. The p-channel MOS transistor 6 is a MOSFET with the same polarity as that of the output transistor 2, and here is a p-channel MOSFET, if the output transistor 2 is a p-channel MOSFET. If the output transistor 2 is an n-channel MOSFET, the MOS transistor 6 is an n-channel MOSFET. The output transistor 2 and the MOS transistor 6 are set so as to have a substantially equal value. In this way, by matching the respective threshold voltages to each other, the drain electrode 5c of the n-channel MOS transistor 5 outputs a voltage equal to a voltage of the internal output node 19 at the time of no signal (no incident light).

For example, the current values of the first and second load circuits 12, 13, and load circuit 54 are all set so as to be equal to one another, and a transistor size of the n-channel MOS transistor 5 and a transistor size of the amplification transistor 1 are set so as to be equal to each other. In addition, a transistor size of the p-channel MOS transistor 6 and a transistor size of the output transistor 2 are set so as to be equal to each other. By setting the current values and the transistor sizes in this way, it is possible to set a transistor with uniform threshold voltage described above. Here, the transistor size is represented by a gate width/a gate length of a MOSFET.

The limiter circuit 30, the bypass circuit 40, and the voltage generation circuit 50 operate as follows.

At the time of no signal, the gate-source voltage Vgs1 of the amplification transistor 1 is output from the output terminal 17. In a state in which the light receiving element 11 outputs a small output current and the limiter transistor 3 does not operate, a voltage which is obtained by doubling an output current of the light receiving element 11 by a transimpedance is output from the output terminal 17. If the threshold voltage Vth1 of the amplification transistor 1 and the gate-source voltage Vgs2 of the output transistor 2 satisfy a relationship of the above-described expression (1), the amplification transistor 1 does not deviate from the saturation region.

If a current which is output from the light receiving element 11 is large and the limiter transistor 3 is turned on, when there is no bypass transistor 4, an equivalent feedback resistance value is decreased. A polarity which is formed by the equivalent feedback resistance value and a capacitance value between the terminals of the light receiving element 11 is formed so as to approach a polarity of an amplification circuit which includes the amplification transistor 1, the first load circuit 12, the output transistor 2, and the second load circuit 13, and thereby an amplification circuit performs an unstable operation such as an oscillation operation. In the light receiving circuit 10b (see FIG. 7), the source electrode 4b of the bypass transistor 4 is maintained as a voltage of the output terminal 50a of the voltage generation circuit 50, that is, a voltage of the drain electrode 5c of the n-channel MOS transistor 5. At this time, if the limiter transistor 3 is turned on, a potential of the internal output node 19 increases, and thereby the bypass transistor 4 is simultaneously turned on with the limiter transistor 3. As the bypass transistor 4 is turned on, a loop gain of an amplification circuit which includes the amplification transistor 1, the first load circuit 12, the output transistor 2, and the second load circuit 13 is decreased, and a stable operation of the amplification circuit is achieved.

The voltage generation circuit 50 may also be an arbitrary circuit which outputs a voltage equal to the internal output node 19 at the time of no signal, and is limited to the configuration described above.

As illustrated in FIG. 8, it may be seen that, in the light receiving circuit 10b, also in frequency characteristics of a large amplitude, that is, pulse response characteristics, distortion due to the saturation of an output waveform does not occur and an output voltage nearly equal to an input current waveform is obtained (graph of a solid line), compared to the light receiving circuit 10 (graph of an alternate long and short dash line) according to the first embodiment. In addition, FIG. 8 illustrates matched waveforms of the output voltage of the light receiving circuit when the bypass circuit 40 and the voltage generation circuit 50 are removed from the light receiving circuit 10b. In the light receiving circuit in which the bypass circuit 40 and the voltage generation circuit 50 have been removed and thus only the limiter circuit 30 operates, the frequency of a polarity is changed at the time of operation of the limiter circuit 30, and an oscillation waveform is observed (graph of dashed line). In contrast to this, the light receiving circuit 10b, according to the present embodiment to which the bypass circuit 40 and the voltage generation circuit 50 are added, generates a stable waveform. In pulse response characteristics of FIG. 8, the power supply voltage Vdd is set as 1.8 V, and resistance values of the feedback resistor elements 14 and 114 are set as 50 kΩ. In addition, a maximum output current of the light receiving element 11 is set as 25 μA, and a capacitance between terminals is set as 10 pF.

In this way, the light receiving circuit 10b has the following effects, in addition to an effect of the light receiving circuit according to another embodiment described above. That is, the light receiving circuit 10b prevents saturation of an output waveform compared to the output current of the light receiving element 11, and thus when a signal with a large amplitude pulse is input, it is possible to obtain a more appropriate output voltage waveform with a small distortion. In addition, when the power supply voltage is lowered, an amplitude of a pulse signal which is input becomes relatively large. However, in the light receiving circuit 10b, a MOS transistor is maintained so as to operate in a saturation region from a minimum output voltage to a maximum output voltage, and thus a dynamic range of an output is secured and a low voltage operation is achieved.

### Fourth Embodiment

FIG. 9 depicts a circuit diagram illustrating a light receiving circuit according to a fourth embodiment.

A light receiving circuit 10c according to the fourth embodiment is different from the light receiving circuit 10 according to the first embodiment in that the light receiving circuit 10c includes a gate ground amplification circuit 70 which is connected between the drain electrode 1c of the amplification transistor 1 and the internal output node 19. Hereinafter, the same symbols or reference numerals are attached to the same circuit elements and connecting as those of the light receiving circuit 10 according to the first embodiment, and detailed description thereof is omitted.

The gate ground amplification circuit 70 includes a cascode transistor 7 (seventh MOS transistor) and bias power supply 72. The bias power supply 72 is connected to the reference potential Vss and supplies the gate ground amplification circuit 70 with an appropriate DC bias. The cascode transistor 7 includes a gate electrode 7a which is connected to the bias power supply 72, a source terminal 7b which is connected to the drain electrode 1c of the amplification transistor 1, and a drain electrode 7c which is connected to the internal output node 19. The gate ground amplification circuit 70 is connected to the drain electrode 1c of the amplification transistor 1 with a low impedance, and outputs to the internal output node 19 with a high impedance. For this reason, the gate ground amplification circuit 70 may reduce a mirror capacitance of the amplification transistor 1, and thus it is possible to improve frequency characteristics of the amplification circuit which includes the amplification transistor 1, the gate ground amplification circuit 70, and the first load circuit 12. In order to increase communication speed of optical communication, implementing of a broad band of a light receiving circuit is preferred, and by using the gate ground amplification circuit 70, it is possible to implement a broad band for a light receiving circuit. According to the light receiving circuit 10c, by using the gate ground amplification circuit 70, a broad band for the light receiving circuit 10c may be implemented, a low voltage operation may be performed, and a dynamic range of the output is expanded.

In the same manner as the light receiving circuit 10, the light receiving circuit 10c needs to satisfy the following conditions, in order to expand the dynamic range of an output by securing a low side level of the dynamic range.

A gate-source voltage of the amplification transistor 1 is referred to as Vgs1, a gate-source voltage of the output transistor 2 is referred to as Vgs2, and a threshold voltage and a gate-source voltage of the cascode transistor 7 are respectively referred to as Vth7 and Vgs7. In addition, if drain voltages at the time of moving from saturation regions of the amplification transistor 1 and the cascode transistor 7 to linear regions are respectively referred to as Vov1 and Vov7, and a voltage value of the bias power supply (first power supply) 72 of the gate of the cascode transistor 7 is referred to as V72 (V7), the following representation is derived.

To begin with, from a condition in which a drain-source voltage Vov7 is satisfied when the cascode transistor 7 moves from a saturation region to a linear region, the following expressions are obtained.

Vgs1−Vgs2−(V72−Vgs7)≧Vov7

∴Vgs1+Vth7−V72≧Vgs2 Expression (6)

In addition, from a condition in which a drain-source voltage Vov1 is satisfied when the amplification transistor 1 moves from a saturation region to a linear region, the following expression is obtained.

V72−Vgs7≧Vov1 Expression (7)

By satisfying expression (6) and expression (7) at the same time, the amplification transistor 1 and the cascode transistor 7 do not deviate from a saturation region, and the light receiving circuit 10c may output a low side output voltage level.

As described above, light receiving circuit 10c has the following effect in addition to the effects of the light receiving circuit according previously described embodiments. That is, by cascode-connecting the gate ground amplification circuit 70 to the amplification transistor 1, a mirror capacitance of the amplification transistor 1 is decreased, and thus the light receiving circuit 10c may achieve a broad band operation.

By applying the gate ground amplification circuit 70 which is used for the light receiving circuit 10c to the light receiving circuit 10b according to the third embodiment, a broad band for a received signal is achieved. That is, light having a wide range of wavelength values maybe input to the light receiving element.

As described above, it is preferable that the amplification transistor 1 and the cascode transistor 7 operate in a saturation region. However, if waveform distortion of the output voltage Vout of the light receiving circuit 10c is sufficiently small or there is no distortion, one or both of the amplification transistor 1 and the cascode transistor 7 may not necessarily operate in the saturation region, in the same manner as in a case of the first embodiment or the like.

### Fifth Embodiment

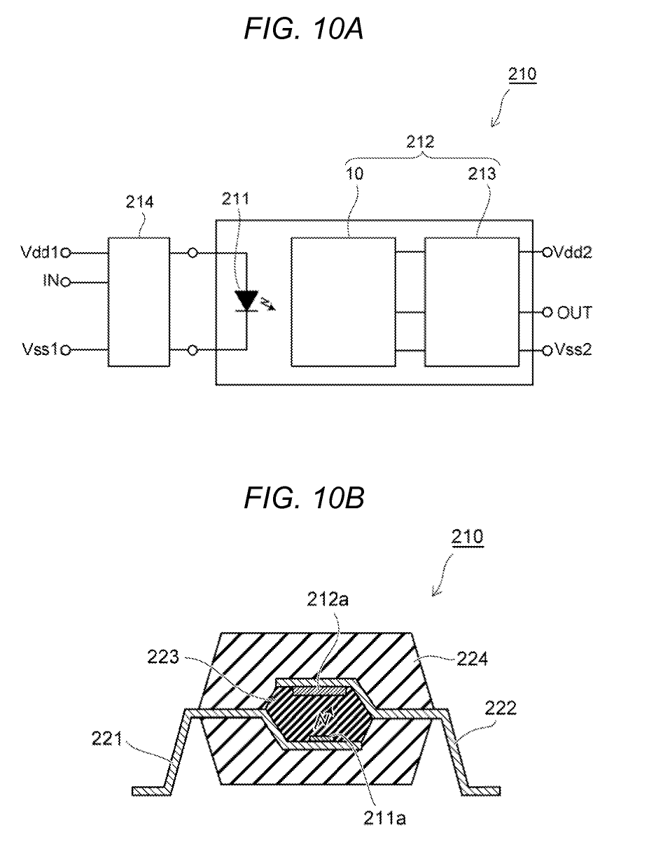

FIG. 10A depicts a block diagram illustrating an optical coupling device according to a fifth embodiment. FIG. 10B is a sectional diagram illustrating a structure of the optical coupling device according to the fifth embodiment.

In the fifth embodiment, a light receiving circuit according to any of the respective embodiments described above is used together with a light transmitting circuit which transmits an optical signal, and may be used as an optical coupling device 210. The optical coupling device 210 is used in environment or the like in which a signal transmission is not performed by directly coupling electrical circuits to each other due to a different voltage level between an input side and an output side. The optical coupling device 210 is, for example, a photocoupler.

As illustrated in FIG. 10A, the optical coupling device 210 includes a light emitting element 211 and a receiving circuit 212.

Here, the light emitting element 211 is an infrared light emitting diode which includes, for example AlGaAs or the like. The light emitting element 211 is driven by a drive circuit 214. The drive circuit 214 is connected to an external power supply which outputs a voltage of, for example, Vdd1−Vss1, and a signal is input from a signal input terminal IN. The light emitting element 211 emits light according to the input signal, and transmits an optical signal to the light receiving circuit 10. Vdd1 is, for example, +5 V, and Vss1 is, for example, −5 V.

Here, for example, the receiving circuit 212 includes the light receiving circuit 10 according to the first embodiment described above, but light receiving circuit 10a, 10b, or 10c could similarly be used. Of course, a light receiving circuit according to another embodiment may be used according to a transmission band or the like. The light receiving circuit 10 converts the received optical signal into a current using light receiving element 11, and the current is converted into a voltage by transimpedance amplification circuit TIA which includes an amplification circuit that includes the amplification transistor 1, the first load circuit 12, the output transistor 2, and the second load circuit 13, and the feedback resistor element 14, and is output (FIG. 1). The receiving circuit 212 may further include a waveform shaping circuit 213. The waveform shaping circuit 213 is connected to an output of the light receiving circuit 10. The waveform shaping circuit 213 includes a comparator having, for example, a predetermined threshold voltage. The waveform shaping circuit 213 compares an analog voltage signal which is output from the light receiving circuit 10 with a threshold voltage, and thereby the analog voltage signal is converted into a digital signal and this digital signal is output from an output terminal OUT. It is preferable that the light receiving circuit 10 and the waveform shaping circuit 213 operate using a common power supply and an operation voltage is Vdd2−Vss2. Vdd2 is, for example, 3.3 V, and Vss2 is, for example, 0 V.

As illustrated in FIG. 10B, the optical coupling device 210 includes lead frames 221 and 222. A light emitting element chip 211a in which the light emitting element 211 is formed on a semiconductor substrate is mounted on the lead frame 221, and is connected to the lead frame 221 by a bonding wire (not specifically illustrated). A receiving circuit chip 212a in which the receiving circuit 212 is formed on the semiconductor substrate is mounted on the lead frame 222, and is connected to the lead frame 222 by a bonding wire (not specifically illustrated). The lead frames 221 and 222 are arranged in such a manner that surfaces on which the light emitting element chip 211a and the receiving circuit chip 212a are mounted face each other. Portions, which are arranged so as to face each other, of the light emitting element chip 211a and the receiving circuit chip 212a are covered with a transparent resin 223 in which optical transmission loss is considered. Furthermore, peripheral portions of the portions are sealed (encapsulated) by epoxy-based light-shielding resin 224 using, for example, a transfer mold technology. The optical coupling device 210 is electrically connected to the drive circuit 214, using a lead of the lead frame 221 on which the light emitting element chip 211a is mounted, and obtains an output signal from a lead of the lead frame 222 on which the receiving circuit chip 212a is mounted.

The optical coupling device 210 may operate using a low voltage, and includes the light receiving circuit 10 which has a wide dynamic range. Thus, the optical coupling device 210 may perform transmission of a signal with a low power consumption between electrically insulated terminals over a wide dynamic range.

### Sixth Embodiment

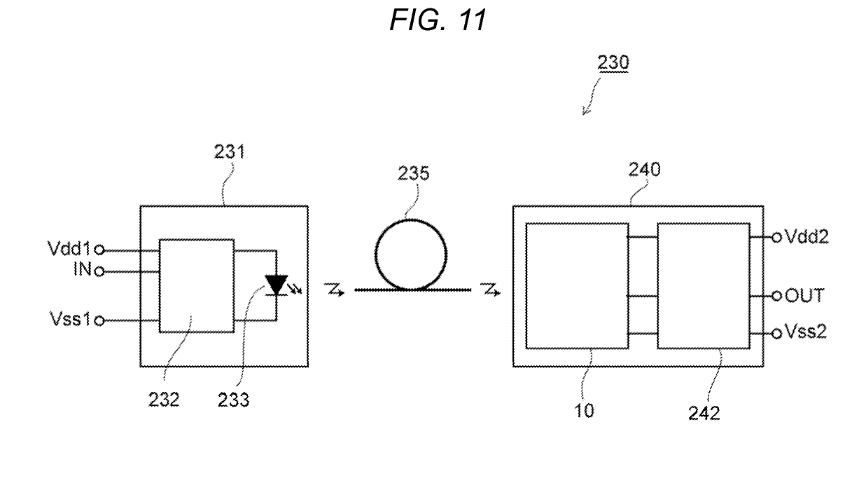

FIG. 11 depicts a block diagram illustrating an optical communication system according to a sixth embodiment.

A light receiving circuit (10, 10a, 10b, 10c) according to the example embodiments described above is used together with a transmission circuit which transmits an optical signal, and may be used as an optical communication system 230. The optical communication system 230 uses an optical signal which is transmitted via an optical fiber 235, converts the optical signal into an electrical signal, and outputs the electrical signal.

The optical communication system 230 according to the sixth embodiment includes a transmission device 231, an optical fiber 235, and a receiving device 240. The transmission device 231 includes a drive circuit 232, and a light emitting element 233, which is driven by the drive circuit 232. The light emitting element 233 of the transmission device 231 is optically connected to the optical fiber 235 at one end of the optical fiber 235. Here, the receiving device 240 includes as an example the light receiving circuit 10 and a waveform shaping circuit 242 which converts an analog signal output from the light receiving circuit 10 into a digital signal. The other end of the optical fiber 235 is optically connected to the light receiving element 11 of the light receiving circuit 10 in the receiving device 240, and the light receiving circuit 10 receives an optical signal which is transmitted via the optical fiber 235. The light receiving circuit 10 converts the optical signal into an analog electrical signal and output the electrical signal to the waveform shaping circuit 242.

The optical communication system 230 according to the sixth embodiment operates using a low voltage, and includes the light receiving circuit 10 having a wide dynamic range, and thus an increase of power consumption is suppressed, a communication distance may be lengthened, an optical signal is received with a high gain even if transmission loss of a transmission path is large, and the optical communication system may perform a stable operation.

In the above embodiments described above, a light receiving circuit may be configured using a MOS transistor with polarity opposite to the MOS transistor which is specifically illustrated.

According to the embodiments described above, it is possible to achieve a light receiving circuit and an optical coupling device which may perform a low voltage operation and perform a stable operation over a wide dynamic range.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A light receiving circuit, comprising:
a light receiving element;
a first MOS transistor of a first conductivity type that has a first gate electrode connected to the light receiving element, a first source electrode connected to a reference voltage terminal, and a first drain electrode connected to a first load circuit at a first node, the first MOS transistor being configured to operate in a saturation region;
a second MOS transistor of a second conductivity type that has a second gate electrode connected to the first node, a second source electrode connected to an output terminal, and a second drain electrode connected to the reference voltage terminal;
a second load circuit connected between a power supply potential line and the second source electrode; and
a feedback resistor element connected between the first gate electrode and the output terminal.

2. The light receiving circuit according to claim 1, further comprising:
a third MOS transistor that has a third gate electrode connected to the output terminal, a third source electrode connected to the first gate electrode, and a third drain electrode;
a voltage generation circuit configured to generate a voltage substantially equal to a voltage of the first node when light is not incident on the light receiving element; and
a fourth MOS transistor connected between the first node and the voltage generation circuit, and having a fourth gate electrode and a fourth drain electrode which are connected to each other.

3. The light receiving circuit according to claim 2, wherein the voltage generation circuit includes:
a third load circuit having a first end connected to the power supply terminal;
a fifth MOS transistor of the first conductivity type that has a fifth gate electrode connected to a second end of the third load circuit, a fifth source electrode connected to the reference voltage terminal, and a fifth drain electrode connected to the fourth source electrode; and
a sixth MOS transistor of the second conductivity type that has a sixth gate electrode and a sixth drain electrode which are both connected to the fifth drain electrode, and a sixth source electrode connected to the fifth gate electrode.

4. The light receiving circuit according to claim 1, further comprising:
a gate ground amplification circuit connected between the first drain electrode and the first node.

5. The light receiving circuit according to claim 4,
wherein the gate ground amplification circuit includes:
a first power supply; and
a seventh MOS transistor of the first conductivity type having a seventh gate electrode connected to an output of the first power supply, a seventh source electrode connected to the first drain electrode, and a seventh drain electrode connected to the first node, wherein
a relationship of Vgs1+Vth7−V7≧Vgs2 and V7−Vgs7≧Vov1 is satisfied when Vgs1 is a voltage between the first gate electrode and the first source electrode, Vth1 is a threshold voltage of the first MOS transistor, Vgs2 is a voltage between the second gate electrode and the second source electrode, Vgs7 is a voltage between the seventh gate electrode and the seventh source electrode, Vth7 is a threshold voltage of the seventh MOS transistor, V7 is an output voltage of the first power supply, and Vov1 is a difference in voltage between Vgs1 and Vth1.

6. The light receiving circuit according to claim 1, wherein a voltage between the second gate electrode and the second source electrode is equal to or less than a threshold voltage of the first MOS transistor.

7. The light receiving circuit according to claim 1, further comprising a second power supply applying a forward bias between the second source electrode and a back gate electrode of the second MOS transistor.

8. A light receiving circuit, comprising:
a light receiving element;
a first MOS transistor of a first conductivity type that has a first gate electrode connected to the light receiving element, a first source electrode connected to a reference voltage terminal, and a first drain electrode connected to a first load circuit at a first node;
a second MOS transistor of a second conductivity type that has a second gate electrode connected to the first node, a second source electrode connected to an output terminal, and a second drain electrode connected to the reference voltage terminal, a voltage between the second gate electrode and the second source electrode being equal to or less than a threshold voltage of the first MOS transistor;
a second load circuit connected between a power supply terminal and the second drain electrode; and
a feedback resistor connected between the first gate electrode and the output terminal.

9. An optical coupling device, comprising:
a light emitting element; and
the light receiving circuit according to claim 8.

10. An amplifier circuit, comprising:
a first MOS transistor of a first conductivity type, the first MOS transistor having a gate connected to an input node of the amplifier circuit, a source connected to a reference voltage terminal, and a drain coupled to a first node;
a second MOS transistor of a second conductivity type, the second MOS transistor having a gate connected to the first node, a source connected to an output of the amplifier circuit, and a drain connected to the reference voltage terminal;
a first current source coupled between the drain of first MOS transistor and a power supply terminal;
a second current source coupled between the source of the second MOS transistor and the power supply terminal; and
a feedback circuit connected between the output of the amplifier circuit and the input node.

11. The amplifier circuit according to claim 10, wherein the feedback circuit is a resistor.

12. The amplifier circuit according to claim 10, wherein the input node is connected to a light receiving element that generates current in response to light received by the light receiving element.

13. The amplifier circuit according to claim 10, further comprising a current mirror circuit that provides current for the first and the second current sources.

14. The amplifier circuit according to claim 10, further comprising a threshold-setting circuit connected between the output of the amplifier and the reference voltage terminal, the threshold-setting circuit configured to adjust a threshold voltage of the second MOS transistor.

15. The amplifier circuit according to claim 14, wherein the threshold-setting circuit includes a resistor and a current source, the resistor having a first end connected to the output of the amplifier and a second end connected to the current source and a back gate electrode of the second MOS transistor.

16. The amplifier circuit according to claim 10, further comprising:
a limiter circuit coupled to the feedback circuit;
a voltage generation circuit connected between the power supply terminal and the reference voltage terminal and having an output terminal at which a reference voltage is output; and
a bypass circuit connected between the first node and the output terminal of the voltage generation circuit.

17. The amplifier circuit according to claim 16, wherein the limiter circuit includes a third MOS transistor and a resistor, the third MOS transistor having a gate connected to the output of the amplifier circuit, a source connected to a first end of the resistor and a drain connected to the power supply terminal, a second end of the resistor being connected to the gate of the first MOS transistor, the third MOS transistor being configured to become conductive when a voltage across the feedback circuit reaches a threshold value.

18. The amplifier circuit according to claim 16, wherein the bypass circuit includes a fourth MOS transistor and a resistor, the resistor being connected to the drain of the first MOS transistor, the fourth MOS transistor having a gate, a source, and a drain, the gate of the fourth MOS transistor being connected to the drain of the fourth MOS transistor, and the source of the fourth MOS transistor being connected to the output terminal of the voltage generation circuit.

19. The amplifier circuit according to claim 16, wherein the voltage generation circuit includes a fifth MOS transistor, a sixth MOS transistor, and a current source, a source of the sixth MOS transistor being connected to a gate of the fifth MOS transistor, the drain of the first MOS transistor being connected to a drain and a gate of the sixth MOS transistor, a source of the fifth MOS transistor being connected to the reference voltage terminal, and the current source being connected between the power supply terminal and the source of the sixth MOS transistor.

20. The amplifier circuit according to claim 10, further comprising:
a first power supply having a first end connected to the reference voltage terminal; and
a gate ground amplifier having a gate terminal connected to a second end of the first power supply, a source terminal connected to the drain of the first MOS transistor, and a drain terminal connected to the first current source.
